(19) United States
(12) Patent Application Publication
(10) Pub. No.: US 2015/0163910 A1
(43) Pub. Date: Jun. 11, 2015

(54) PRINTED CIRCUIT BOARD

(71) Applicants: HONG FU JIN PRECISION INDUSTRY (WuHan) CO., LTD., Wuhan (CN); HON HAI PRECISION INDUSTRY CO., LTD., New Taipei (TW)

(72) Inventors: NIAN MIN, Wuhan (CN); HOU-YUAN CHOU, New Taipei (TW); BING CHEN, Wuhan (CN)

(21) Appl. No.: 14/540,151

(22) Filed: Nov. 13, 2014

(30) Foreign Application Priority Data
Dec. 11, 2013 (CN) 201310668710.7

(51) Int. Cl. H05K 1/11; H05K 1/02

(52) U.S. Cl. CPC H05K 1/116; H05K 1/0298; H05K 2201/09709

(57) ABSTRACT

A printed circuit board includes a first signal layer, a second signal layer, a third signal layer located between the first and second signal layers, a ground layer located between the second and third signal layers, first transmission line located on the first signal layer, a second transmission line located on the third layer, a via passing through the printed circuit board, and annular solders defined on the first, second, and third signal layers respectively and surrounding the via. The via is isolated from the ground layer and electronically coupled to the first and second transmission lines through the annular solder. A distance between the ground layer and the via is greater than a radius difference of the annular solder on the second signal layer.

### FIELD

The subject matter herein generally relates to printed circuit boards.

### BACKGROUND

Vias are defined in multilayer printed circuit boards for transmitting signals between different layers.

### BRIEF DESCRIPTION OF THE DRAWINGS

Implementations of the present technology will now be described, by way of example only, with reference to the attached figures.

FIG. 1 is a schematic diagram of an embodiment of a printed circuit board.

FIG. 2 is a top view of the printed circuit board of FIG. 1.

FIG. 3 is a simulation graph showing insertion loss for the printed circuit board of FIG. 1 and a conventional printed circuit board.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “comprising,” when utilized, means “including, but not necessarily limited to”; it specifically indicates open-ended inclusion or membership in the so-described combination, group, series and the like.

The present disclosure is described in relation to a multi-layer printed circuit board.

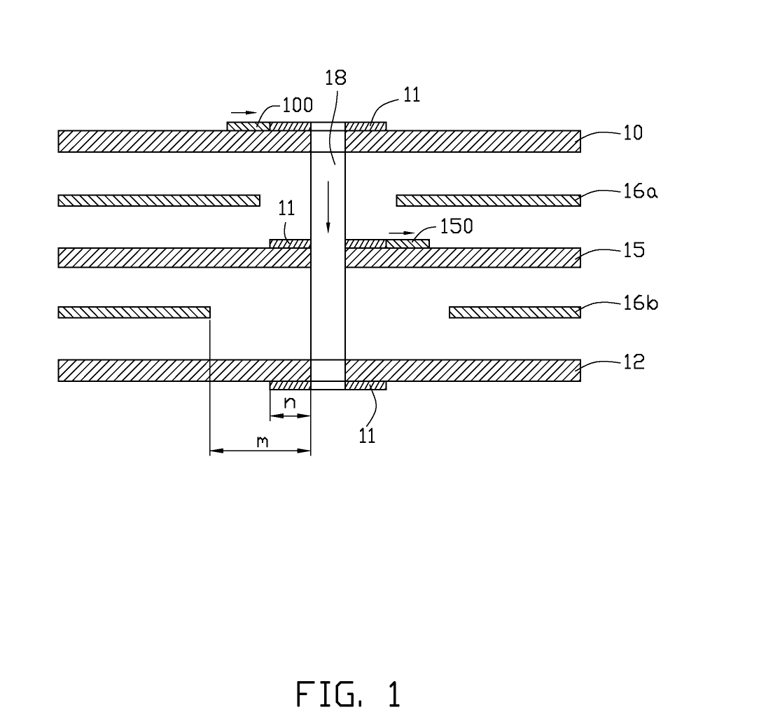

FIG. 1 illustrates an embodiment of the multi-layer printed circuit board. The printed circuit board can comprise a first signal layer 10, a second signal layer 12, a third signal layer 15, a first ground layer 16a, a second ground layer 16b, and a via 18. A transmission line 100 is located on the first signal layer 10, and a transmission line 150 is located on the third signal layer 15. In some embodiments, the printed circuit board can further comprise other layers.

The first signal layer 10 is the top layer of the printed circuit board. The second signal layer 12 is the bottom layer of the printed circuit board. The first ground layer 16a and the second ground layer 16b are located between the first signal layer 10 and the second signal layer 12. The third signal layer 15 is located between the first ground layer 16a and the second ground layer 16b, and the second ground layer 16b is located between the third signal layer 15 and the second signal layer 12.

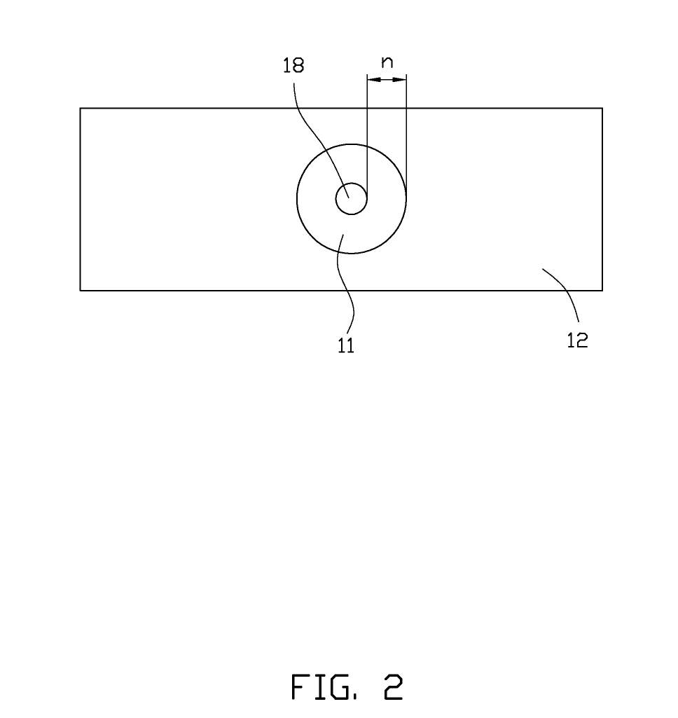

FIG. 2 illustrates a top view of the printed circuit board. The via 18 passes through the printed circuit board, and is isolated from the first ground layer 16a and the second ground layer 16b. Annular solder 11 is defined on the first signal layer 10, the second signal layer 12, and the third signal layer 15 respectively and surrounds the via 18. The via 18 is electrically coupled to the transmission lines 100 and 150 through the annular solder. A distance m between the second ground layer 16b and the via 18 is considerably larger than a radius difference n of the annular solder 11. A first terminal of the transmission line 100 is coupled to a first electronic element (not shown). A second terminal of the transmission line 100 is coupled to the via 18. A first terminal of the transmission line 150 is coupled to the via 18. A second terminal of the transmission line 150 is coupled to a second electronic element (not shown). The via 18 transmits signals from the transmission line 100 to the transmission line 150.

When the via 18 transmits signals from the transmission line 100 to the transmission line 150, capacitance effects between the annular solder 11 defined on the second signal layer 12 and the second ground layer 16b, and between the annular solder 11 defined on the third signal layer 15 and the second ground layer 16b, is prevented.

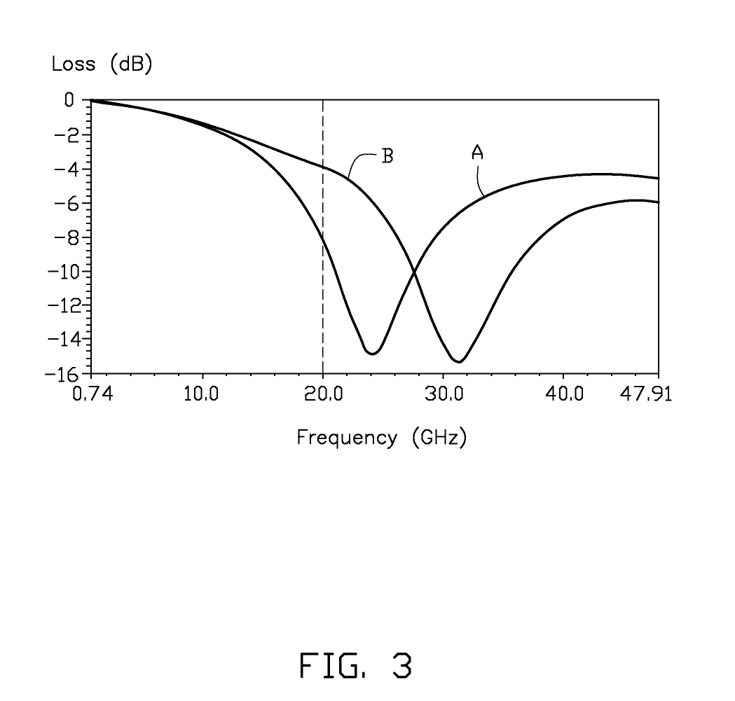

FIG. 3 illustrates a simulation graph of insertion loss for the printed circuit board of FIG. 1 and a conventional printed circuit board. A curve A denotes an insertion loss for the conventional printed circuit board which has capacitance effects. A curve B denotes an insertion loss for the printed circuit board which has no capacitance effects. FIG. 3 illustrates that an x-coordinate denotes frequency of signals on the printed circuit board, a y-coordinate denotes insertion loss of the printed circuit board.

FIG. 3 illustrates in general, an insertion loss on the printed circuit board is lower than the insertion loss on the conventional printed circuit board, especially at a signal frequency of 20 Hertz (Hz).

The embodiments shown and described above are only examples. Even though numerous characteristics and advantages of the present technology have been set forth in the foregoing description, together with details of the structure and function of the present disclosure, the disclosure is illustrative only, and changes may be made in the detail, especially in matters of shape, size and arrangement of the parts within the principles of the present disclosure up to, and including, the full extent established by the broad general meaning of the terms used in the claims. It will therefore be appreciated that the embodiments described above may be modified within the scope of the claims.

What is claimed is:

1. A printed circuit board comprising:
a first signal layer;
a second signal layer;
a third signal layer located between the first and second signal layers;
a first ground layer located between the first and third signal layers;
a second ground layer located between the second and third signal layers;
a first transmission line located on the first signal layer;
a second transmission line located on the third layer;
a via passing through the printed circuit board; and
annular solder defined on the first, second, and third signal layers respectively and surrounding the via;
wherein the via is isolated from the first and second ground layers and electronically coupled to the first and second transmission lines through the annular solder; and
wherein a distance between the second ground layer and the via is greater than a radius difference of the annular solder on the second signal layer.

2. The printed circuit board of claim 1, wherein the first signal layer is a top layer of the printed circuit board.

3. The printed circuit board of claim 1, wherein the second signal layer is a bottom layer of the printed circuit board.

4. A printed circuit board comprising:
a first signal layer;
a second signal layer;
a third signal layer located between the first and second signal layers;
a ground layer located between the second and third signal layers;
a first transmission line located on the first signal layer;
a second transmission line located on the third layer;
a via passing through the printed circuit board; and
annular solder defined on the first, second, and third signal layers respectively and surrounding the via;
wherein the via is isolated from the ground layer and electronically coupled to the first and second transmission lines through the annular solder; and
wherein a distance between the ground layer and the via is greater than a radius difference of the annular solder on the second signal layer.

5. The printed circuit board of claim 4, wherein the first signal layer is a top layer of the printed circuit board.

6. The printed circuit board of claim 4, wherein the second signal layer is a bottom layer of the printed circuit board.
